(19) United States
(12) Patent Application Publication
(10) Pub. No.: US 2026/0089929 A1
(43) Pub. Date: Mar. 26, 2026

(54) MEMORY DEVICE, FABRICATION METHOD AND MEMORY SYSTEM

(71) Applicant: Yangtze Memory Technologies Co., Ltd., Wuhan (CN)

(72) Inventors: Zhiliang XIA, Wuhan (CN); Wei LIU, Wuhan (CN); Zongliang HUO, Wuhan (CN)

(21) Appl. No.: 19/176,457

(22) Filed: Apr. 11, 2025

(30) Foreign Application Priority Data
Sep. 25, 2024 (CN) 202411345930.0

(51) Int. Cl. H10B 12/00; H01L 23/00; H01L 25/18

(52) U.S. Cl. CPC H10B 12/482; H10B 12/02; H10B 12/315; H10W 90/00; H10W 90/20; H10W 90/792

(57) ABSTRACT

Memory devices, memory systems, and fabrication methods of the memory devices are provided. In one aspect, a memory device includes: semiconductor bodies extending in a first direction, a semiconductor body including a first end and a second end opposite to each other in the first direction; a bit line extending in a second direction intersecting with the first direction and being located on a side of the semiconductor body proximate to the first end and coupled to the first end of the semiconductor body; a first dielectric layer located between at least two adjacent semiconductor bodies including the semiconductor body and at least partially covering sidewalls of the first end of the semiconductor body; and a second dielectric layer located between the at least two adjacent semiconductor bodies. The first dielectric layer is located between the second dielectric layer and the semiconductor body.

### CROSS-REFERENCE TO RELATED APPLICATIONS

This application claims priority to Chinese Patent Application No. 202411345930.0, filed on Sep. 25, 2024, which is hereby incorporated by reference in its entirety.

### TECHNICAL FIELD

The present disclosure relates to the field of semiconductor technology, particularly to a memory device and a fabrication method thereof as well as a memory system.

### BACKGROUND

A memory apparatus is a storage device used for saving information in modern information technology. Some semiconductor memories including some nonvolatile memories and volatile memories have gradually been main stream products in the memory market since they have relatively high memory density, controllable fabrication cost, suitable read/write speed and retention capability. However, there is much room for improvement of memory devices and fabrication methods thereof with increasing demands for the storage device.

### SUMMARY

According to some aspects of examples of the present disclosure, a memory device is provided, the memory device including: semiconductor bodies each extending in a first direction and including a first end and a second end disposed opposite to each other in the first direction; a bit line extending in a second direction; the bit line located on a side of the semiconductor body proximate to the first end in the first direction and coupled to the first end of the semiconductor body; a first dielectric layer located between at least two adjacent ones of the semiconductor bodies and at least partially covering sidewalls of the first end of the semiconductor body extending in the first direction; the second direction intersecting the first direction; and a second dielectric layer located between the at least two adjacent ones of the semiconductor bodies, wherein the first dielectric layer is located between the second dielectric layer and the semiconductor body.

In some examples, the memory device further includes: a gate layer extending in a third direction, the gate layer located between the at least two adjacent ones of the semiconductor bodies, covering sidewalls between the first end and second end of the semiconductor body extending in the first direction, and located on a side of the first dielectric layer away from the bit line in the first direction; wherein the third direction intersects with the second direction, and a plane formed by the second direction and the third direction intersects with the first direction.

In some examples, a portion of the first dielectric layer extending in the second direction at least partially covers the gate layer.

In some examples, the memory device further includes: conductive structures each extending in the third direction and located at an end of the first dielectric layer away from the bit line, wherein the gate layer is located between at least two adjacent ones of the conductive structures.

In some examples, the memory device further includes: a semiconductor strip extending in the second direction, the semiconductor strip located between the bit line and the semiconductor body and connected to the first end of the semiconductor body, wherein the first dielectric layer includes: a first portion at least partially covering sidewalls of the first end of the semiconductor body extending in the first direction and at least partially covering the area of the semiconductor strip between two adjacent ones of the semiconductor bodies; and a second portion protruding from the first portion towards the gate layer in the first direction, wherein a portion of the second portion extending in the second direction at least partially covers the gate layer.

In some examples, the portion of the first dielectric layer extending in the second direction at least partially covers the area between two adjacent ones of the semiconductor bodies.

In some examples, a cross section of the first dielectric layer in a first plane has a shape of closed figure with the first plane being a plane formed by the first direction and the second direction and the closed figure includes: at least one of straight lines or arcs.

In some examples, the first dielectric layer further includes: a third portion located between at least two adjacent semiconductor bodies in the third direction, extending in a second plane formed by the first direction and the second direction, and at least partially covering the sidewalls of the first end of the semiconductor body extending in the first direction; wherein the third direction intersects with the second direction and a plane formed by the second direction and the third direction intersects with the first direction.

In some examples, the bit line is located at one end of the third portion of the first dielectric layer in the first direction and the third portion is spaced apart from the bit line in the first direction.

In some examples, the first dielectric layer further includes: a fourth portion located between at least two adjacent semiconductor bodies in the second direction, wherein an end of the third portion of the first dielectric layer proximate to the bit line in the first direction has a first distance from the bit line, an end of the fourth portion proximate to the bit line in the first direction has at a second distance from the bit line, and the first distance is smaller than or equal to the second distance.

In some examples, the memory device further includes: an isolation structure located between the at least two adjacent ones of the semiconductor bodies, wherein the isolation structure includes the first dielectric layer, the second dielectric layer and an air gap enclosed by the second dielectric layer, the air gap being proximate to the bit line in the first direction.

In some examples, the portion of the first dielectric layer covering the sidewalls of the first end of the semiconductor body extending in the first direction has a thickness in the second direction, which is in a range from 0.1 nm to 2 nm.

In some examples, the first dielectric layer includes a negative charge.

In some examples, the first dielectric layer has a dielectric constant larger than that of the second dielectric layer and is made of a material including at least one of aluminum oxide and hafnium oxide.

In some examples, a range of the dielectric constant of the first dielectric layer includes 5˜40.

According to some aspects of examples of the present disclosure, a fabrication method of a memory device is provided, the method including: providing semiconductor bodies each extending in a first direction and including a first end and a second end disposed opposite to each other in the first direction, wherein a first dielectric material is filled between at least two adjacent ones of the semiconductor bodies, a second direction intersects with the first direction, a third direction intersects with the second direction, and a plane formed by the second direction and the third direction intersects with the first direction; etching the first dielectric material between the first ends adjacent in the third direction to form a first trench extending in the second direction, wherein the sidewalls of the first trench expose a cavity between the first ends adjacent in the second direction; forming a first dielectric layer on the sidewalls of the first trench and the inner walls of the cavity, the first dielectric layer at least partially covering the sidewalls of the first end of the semiconductor body extending in the first direction; and filling a second dielectric material in the first trench to form a second dielectric layer in both the trench and the cavity.

In some examples, the fabrication method further includes: penetrating through the first dielectric layer on the bottom of the first trench in the first direction.

In some examples, the cross section of the first dielectric layer in a first plane has a shape of closed figure with the first plane being a plane formed by the first direction and the second direction and the closed figure includes: at least one of straight lines or arcs.

In some examples, the fabrication method further includes: forming a first dielectric material layer on the sidewalls of the first trench and the inner walls of the cavity; filling the first trench and the cavity to form a sacrificial structure; etching the first dielectric material layer in the first trench to lower the height of the top surface of the first dielectric material layer in the first trench in the first direction, to form the first dielectric layer; and removing the sacrificial structure to form the second dielectric layer.

In some examples, the fabrication method further includes: filling a portion of the space within the first trench with the second dielectric material and filling a portion of the space within the cavity with the second dielectric material, wherein the second dielectric layer encloses an air gap.

In some examples, the fabrication method further includes: etching the first dielectric material layer to form a second trench extending in the second direction, wherein the bottom of the second trench is above or flush with the top inner wall of the cavity.

In some examples, the cavity exposes a conductive material layer between the adjacent semiconductor bodies and at least partially covering the sidewalls of the semiconductor body extending in the first direction; and the fabrication method further includes: etching a portion of the conductive material layer exposed from the cavity through the first trench to penetrate through, in the first direction, the portion of the conductive material layer extending in the second direction, to form the gate layer; and forming the first dielectric layer on the gate layer, wherein the portion of the first dielectric layer extending in the second direction at least partially covers the gate layer.

In some examples, the fabrication method further includes: etching the gate layer along the first direction to reduce the dimension of the gate layer in the first direction, so as to form the third trench extending in the third direction on the gate layer, the third trench communicating with the cavity; and forming the first dielectric layer on the inner wall of the cavity and the inner wall of the third trench.

In some examples, the fabrication method further includes: forming the bit line extending in the second direction on the side of the semiconductor body proximate to the first end, wherein the bit line is coupled to the first end of the semiconductor body.

In some examples, the first end of the semiconductor body is connected by the semiconductor strip and the first trench is located between adjacent semiconductor strips; and the method of forming the bit line includes: forming the bit line based on the semiconductor strip, wherein at least a portion of the bit line is in the semiconductor strip and the bit line is located above the first dielectric layer.

According to some aspects of examples of the present disclosure, a memory system is provided, the memory system including: said memory device; and a memory controller coupled to and controlling the memory device.

Examples of the present disclosure provide a memory apparatus, which includes: semiconductor bodies each extending in a first direction and having a first end and a second end disposed opposite to each other in the first direction, the first end of the semiconductor body being coupled to a bit line; a first dielectric layer located between two adjacent semiconductor bodies and at least partially covering sidewalls of the first end of the semiconductor body extending in the first direction, wherein the first dielectric layer provides electrical isolation for the first end of the semiconductor body and may repel the charge on the sidewalls of the first end to reduce electrical leakage from the first end; and a second dielectric layer located between two adjacent semiconductor bodies and covering the first dielectric layer to enhance electrical isolation between the adjacent semiconductor bodies and thus reduce electrical leakage; wherein the second dielectric layer may provide a relatively small dielectric constant and reduce the parasitic capacitance between the adjacent semiconductor bodies.

### BRIEF DESCRIPTION OF DRAWINGS

FIG. 1 is a schematic diagram illustrating a memory array according to an example implementation;

FIGS. 2 to 9 are schematic diagrams illustrating an example memory device according to an example of the present disclosure;

FIG. 10 is a flowchart illustrating a fabrication method of an example memory device according to an example of the present disclosure;

FIGS. 11 to 20 are schematic diagrams illustrating fabrication of an example memory device according to an example of the present disclosure; and

FIGS. 21 and 22 are schematic diagrams illustrating an example system according to an example of the present disclosure.

### DETAILED DESCRIPTION

Hereinafter, example implementations disclosed by the present disclosure will be described in more detail with reference to accompanying drawings. Although example implementations of the present disclosure are illustrated in accompanying drawings, it should be understood, however, that the present disclosure can be embodied in various forms and is not limited to specific implementations described herein. On the contrary, the implementations are provided for more thorough understanding of the present disclosure and to convey the scope disclosed by the present disclosure fully to those skilled in the art.

In the description hereafter, many specific details are provided to facilitate more thorough understanding of the present disclosure. However, it is apparent for those skilled in the art that the present disclosure can be implemented without one or more of these details. In other examples, in order not to obscure the present disclosure, some technical features well known in the art will not be described. That is to say, not all of the features in actual examples will be described herein and well-known functions and structures will not be described in detail.

It should be appreciated that when an element or a layer is said to be “over”, “adjacent to”, “connected to” or “coupled to” another element or layer, it may be directly over, adjacent to, connected to or coupled to the other element or layer, or an intervening element or layer may exist therebetween. On the contrary, when an element is said to be “directly on”, “directly adjacent to”, “directly connected to” or “directly coupled to” another element or layer, there is no intervening element or layer therebetween. It should be appreciated that although various elements, components, regions, layers and/or parts may be described using terms “first”, “second”, “third” or the like, they are not limited by those terms. The terms are only used to distinguish one element, component, region, layer or part from another element, component, region, layer or part. Therefore, a first element, component, region, layer or part discussed hereafter may be instead expressed as a second element, component, region, layer or part without departing from the teaching of the present disclosure. When a second element, component, region, layer or part is in discussion, it is not intended to indicate that a first element, component, region, layer or part must exist.

Spatially relative terms, such as “below”, “beneath”, “lower”, “under”, “over” and “above”, are used herein for ease of description to explain the relationship of one element or feature with respect to other elements or features as shown in the figures. It should be appreciated that, in addition to the orientations shown in the figures, different orientations of devices in use and operation are also intended to be covered by those spatially relative terms. For example, if a device in the figure is turned upside down, the element or feature described to be “beneath”, “under” or “below” another element or feature will have the orientation of being “over” the other element or feature. Therefore, the example terms “beneath” and “below” may include orientations of both “over” and “under”. Devices may be otherwise oriented (rotated 90 degrees or at other orientations) and the spatially relative descriptors used herein may likewise be interpreted accordingly.

Terminology is used herein only for description of specific examples and in no way for limiting the present disclosure. As used herein, the terms “a”, “an” and “said/the” in singular forms are also intended to cover their plural forms, unless the context clearly indicates otherwise. It is also be appreciated that terms “consist”, “comprise”, “constitute” and/or “include”, as used in the specification, identify the presence of the mentioned features, integers, steps, operations, elements and/or components, but do not exclude the presence or addition of one or more other features, integers, steps, operations, elements, components and/or combinations thereof. As used herein, the term “and/or” includes any and all combinations of relevant listed items.

It can be understood that “some example” or “an example” mentioned throughout the specification means that particular features, structures or characteristics in association with the example may be included in at least one example of the present disclosure. Therefore, “in some example” or “in an example” mentioned throughout the specification refers not necessarily to the same example. Moreover, those particular features, structures or characteristics may be incorporated in one or more examples in any suitable manner. It can be understood that, in various examples of the present disclosure, the size of the sequence numbers of the above processes does not necessarily mean the order of execution, and the execution order of various processes should be determined based on their functions and inherent logic, instead of imposing any limitation to the implementation of examples of the present disclosure.

Some memory devices, for example, including dynamic random access memories (DRAMs), may include a memory array and a peripheral circuit that may control the memory array and operate the memory array to perform read, write or refresh operations. A memory device provided in an example of the present disclosure may be a memory apparatus or a part thereof. The memory device may be a DRAM or part of the memory devices in a DRAM.

Alternatively, a memory apparatus may include a DRAM, which then includes the memory device of the present disclosure, which is applicable to a double data rate synchronous dynamic random access memory using DDR4 and DDR5 memory specifications, a low power consumption double data rate synchronous dynamic random access memory using DDR5 memory specification.

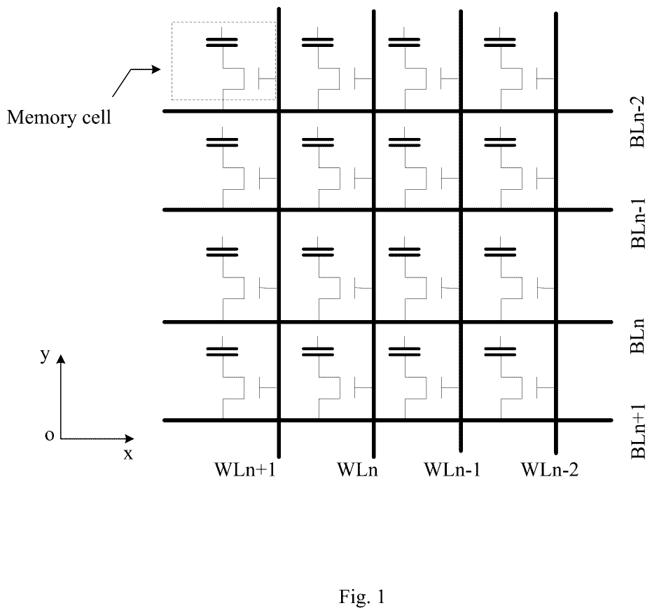

In a DRAM, a memory array may be arranged in rows and columns, so that a memory cell may be addressed by designating the row and the column of the array where the memory cell is located. The memory array may include a plurality of word lines corresponding to the rows and a plurality of bit lines corresponding to the columns. The word lines intersect with the bit lines. Memory cell at the intersection of the selected word line and the selected bit line can be selected for read, write or refresh operations. As illustrated in FIG. 1, the memory array may include a plurality of word lines WLn, WLn+1, WLn−1 and WLn−2 and a plurality of bit lines BLn, BLn+1, BLn−1 and BLn−2 intersecting with the word lines. Memory cells in the memory array may include capacitors and transistors and one memory cell may include one transistor and one capacitor. A word line may be a conductive structure such as a gate layer or the like and acts as the gate of the transistor. One controlled terminal (the source) of the transistor is coupled to one electrode of the capacitor and the other controlled terminal (the drain) of the transistor is coupled to the bit line. The other electrode of the capacitor may be grounded or applied with another voltage (e.g., Vcc/2). As shown in FIG. 1, the memory cell array is arranged in an array of x columns and y rows with the rows being or not being perpendicular to the columns. A z direction may be the vertical direction or the thickness direction of the device and may be the first direction in examples of the present disclosure. An xoy plane intersects with and is perpendicular to the z direction. The x direction may be the second direction and the y direction may be the third direction in examples of the present disclosure. The word line or the row may extend in a direction that is parallel to the y direction or forms an angle with respect to the y direction. The bit line or the column may extend in a direction that is parallel to the x direction or forms an angle with respect to the x direction. The orthogonal projection of the word line on the xoy plane is perpendicular to, or otherwise forms an angle with respect to, that of the bit line on the xoy plane.

In some examples, during a read or write operation, the corresponding word line may be selected with a word line selection signal and the corresponding bit line may be selected according to a column selection signal; when the word line and the bit line are selected simultaneously, the selected memory cell may be located and at this point the transistor in the selected memory cell may be turned on due to application of the operation voltage on the word line, so that a read, write or refresh operation may be performed on the selected memory cell. In some examples, the capacitor may be replaced by another memory structure including, but not limited to, a phase change memory structure, a resistance change memory structure or a magnetic change memory structure, or the like.

In some examples, logical 1 and 0 may be represented by the more or less of the charge stored in the capacitor or by the high or low of the voltage difference across the two ends of the capacitor. The voltage signal on the word line is applied to the gate to control the transistor on or off, enabling the capacitor to be selected or deselected and in turn enabling the data information stored in the capacitor to be read through the bit line or data to be written in the capacitor for storage through the bit line.

In some examples, a DRAM memory device or a DRAM memory apparatus may further include a peripheral circuit coupled to the memory array in FIG. 1. Illustratively, the peripheral circuit may include, but not limited to, a sense amplifier circuit, a row decoding circuit, a column decoding circuit, a voltage generating circuit and the like. The sense amplifier circuit is coupled to bit lines and may be configured to capture the weak voltage fluctuation on the bit line and locally restore the voltage of the capacitor of the memory cell according to the voltage fluctuation. The sense amplifier circuit may include a latch to latch the restored voltage value of the capacitor, enabling the information stored in the memory cell to be transferred to the amplifier circuit from the capacitor. The sense amplifier circuit may include a differential sense amplifier circuit coupled to two bit lines and use one selected bit line and one complementary bit line (acting as a reference line) for operation, to detect and amplify the voltage difference between a pair of bit lines. The row decoding circuit is configured to address the memory array and apply an operation voltage on the word line. The column decoding circuit is configured to address the memory array and apply or receive the bit line voltage. The voltage generating circuit generates high and low voltages required for various devices.

In some examples, the peripheral circuits may include a CMOS structure or CMOS circuit including a digital or analog circuit composed of transistors, to control, or supply power to, the memory array. Improving the integration degree of devices in the peripheral circuit facilitates to improve the integration degree of the whole memory device, and improving the stability of the devices in the peripheral circuit facilitates to improve the operation stability of the memory device.

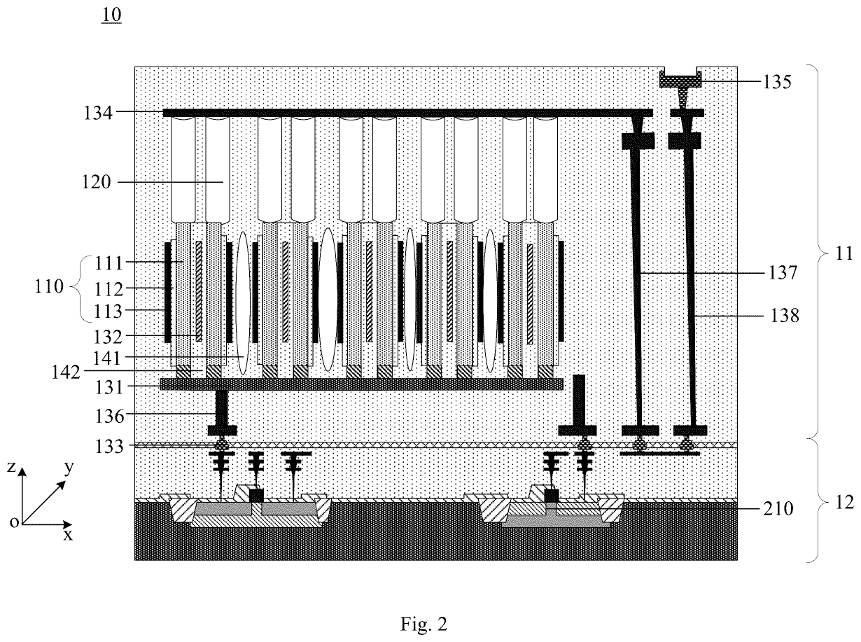

According to some aspects of examples of the present disclosure, FIG. 2 provides a memory device 10 including a first semiconductor structure 11 and a second semiconductor structure 12 disposed in the z direction. The first semiconductor structure 11 may be coupled to interconnect through mixed bonding, the first semiconductor structure 11 coupled with the second semiconductor structure 12 using bonding contacts 133 extending through a bonding interface that includes a dielectric layer. Alternatively, the first semiconductor structure 11 is formed over the second semiconductor structure 12 without any bonding contacts 133 disposed. The first semiconductor structure 11 may include a memory array that may include a DRAM, a phase change memory structure, a resistance change memory structure or a magnetic change memory structure. The memory device 10 as shown in FIG. 2 may act as a DRAM memory apparatus or a part thereof. The first semiconductor structure 11 may include a DRAM memory array including transistors 110 and capacitor structures 120 coupled to the transistors 110. In some implementations, the capacitor structure 120 in FIG. 2 may be replaced by a phase change memory structure, a resistance change memory structure and a magnetic change memory structure to constitute another memory device 10. The second semiconductor structure 12 may include a peripheral circuit 210 coupled to and controlling the memory array to perform read, write and other operations.

Referring to FIG. 2, the first semiconductor structure 11 may include: a semiconductor body 111 that may include a semiconductor pillar extending in the z direction and having a first end and a second end disposed opposite to each other in the z direction; a gate layer 113 extending in the y direction, covering sidewalls of the semiconductor body 111 extending along the z direction, for example, the gate layer 113 covering the sidewalls of the semiconductor body 111 between the first end and the second end, the gate layer 113 acting as a control gate for the transistor 110 to control the transistor 110 on or off; and a gate dielectric layer 112 between the semiconductor body 111 and the gate layer 113. The cross section of the semiconductor body 111 in an xoy plane may have a shape including, but not limited to, a rectangular shape, a quadrangle shape, other polygon shape, a circular shape, an ellipse shape or other irregular figure or the like. The present disclosure is not limited in this respect.

One semiconductor body 111, one gate layer 113 and one dielectric layer 112 may constitute one transistor 110. A dielectric material 142 may be filled between adjacent transistors 110 and may include or enclose an air gap 141 to reduce the induced capacitance. A conductive structure 132 may be disposed between adjacent semiconductor bodies 111 to reduce crosstalk between adjacent gate layers 113. The conductive structure 132 and the gate layer 113 may be disposed on two opposite sides of one semiconductor body 111 in the x direction. When the gate layer 113 is applied with a turn-on voltage of the transistor 110, the conductive structure 132 may be grounded or applied with a fixed voltage (e.g., a negative voltage) to reduce crosstalk between the transistors 110. The fixed voltage may be a fixed voltage value designated through test during the phase of ex-factory test for the memory device, or may be a designated voltage interval. Illustratively, taking two adjacent conductive structures 132 as an example, two semiconductor body 111 may be disposed between the two adjacent conductive structures 132, two gate layers 113 facing each other may be disposed between the two semiconductor bodies 111, and an air gap 141 may be disposed between the two gate layers 113 facing each other. In FIG. 2, one semiconductor body 111 may correspond to one gate layer 113 and two semiconductor bodies 111 may share one conductive structure 132. In other examples, in order to improve the gate control performance of the semiconductor body 111, one semiconductor body 111 may be provided with two gate layers 113 or an all-around gate layer 113 surrounding the sidewalls of the semiconductor body 111. For adaption to improvement of integration degree of the memory device 10 and reduction of parasitic capacitance and parasitic resistance, the conductive structures 132 may also be arranged in another manner, for example, one semiconductor body 111 may correspond to one conductive structure 132.

The first end and the second end of the semiconductor body 111 in the z direction may have the same type of doping to serve as a first active area and a second active area, which serve as the drain and the source of the transistor 110, the drain and the source being exchangeable in location. The middle area between the first end and the second end may have an opposite type of doping to that of the first end to serve as the channel of the transistor 110. The first end of the semiconductor body 111 is at the bottom in the negative z direction in FIG. 2 and coupled to the bit line 131 extending in the x direction, and the second end of the semiconductor body 111 is at the top in the positive z direction in FIG. 2 and coupled to the capacitor structure 120. A side of the first end of the semiconductor body 111 proximate to the bit line 131 may be heavily doped, or form metal silicide to reduce the contact resistance between the semiconductor body 111 and the bit line 131. The bit line 131 may include a metallic conductive material or a metal-semiconductor compound. For example, the semiconductor body 111 may include silicon and the bit line 131 may include metal silicide, such as tungsten silicide or titanium silicide; or the bit line 131 may include a metal silicide layer and a metal layer deposited on a side of the metal silicide layer away from the semiconductor body 111 to constitute the bit line. The metal layer may include, but not limited to, tungsten, copper, aluminum, etc.

The gate layer 113 may serve as a word line and one gate layer 113 may correspond to a plurality of semiconductor bodies 111 arranged in the y direction. The bit line 131 extends in the x direction and one bit line 131 may correspond to a plurality of semiconductor bodies 111 arranged in the x direction. When the gate layer 113 and the bit line 131 are selected, the semiconductor body 111, to which the gate layer 113 and the bit line 131 correspond simultaneously, may be selected and turned on to select the capacitor structure 120, so that the capacitor structure 120 may be charged/discharged or sensed for an amount of charge to perform write, refresh, read or other operations. In examples of the present disclosure, there may be no limitation on the specific structure of the capacitor structure 120. The capacitor structure 120 may include a first electrode, a dielectric layer and a second electrode with the dielectric layer electrically isolating the first electrode from the second electrode. One electrode of the capacitor structure 120 may extend in the z direction and have a pillar shape.

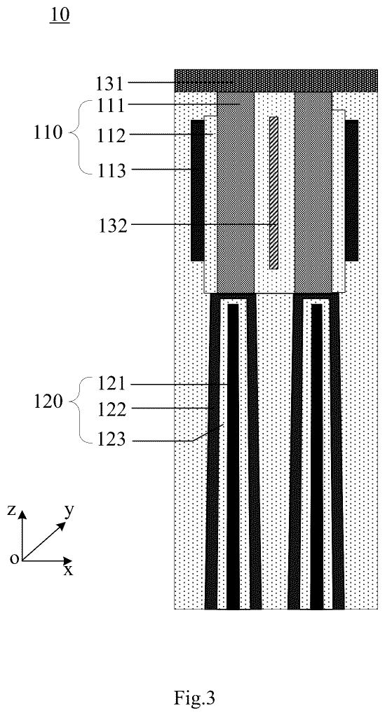

Referring to the partially enlarged view of the transistor 110 and the capacitor structure 120 illustrated in FIG. 3, the capacitor structure 120 may include a first electrode 121 extending in the z direction, a dielectric layer 123 surrounding the first electrode 121 and a second electrode 122 surrounding the dielectric layer 123, with the dielectric layer 123 located between the first electrode 121 and the second electrode 122, and the second electrode 122 coupled to the second end of the semiconductor body 111 away from the bit line 131. The end of the capacitor structure 120 away from the semiconductor body 111 in the z direction has a dimension in the x direction larger than or equal to that of the end of the capacitor structure 120 proximate to the semiconductor body 111 in the z direction. The first electrodes 121 of the plurality of capacitor structures 120 may be coupled to an interconnect layer (e.g., the first interconnect layer 134 in FIG. 2) so as to be grounded or applied with other operation voltages; or the plurality of capacitor structures 120 share one first electrode 121 and the end of the first electrode 121 away from the semiconductor body 111 has a film layer structure extending in the x direction and/or the y direction. When the first electrode 121 is grounded or applied with other operation voltages, the plurality of capacitor structures 120 share the first electrode 121 and are applied with a common voltage.

In some examples, a contact may be disposed between the capacitor structure 120 and the semiconductor body 111, and the semiconductor body 111 is coupled to the capacitor structure 120 through the contact; the contact may include metal silicide, e.g., titanium silicide, to reduce the contact resistance between the capacitor structure 120 and the semiconductor body 111 and enhance adhesion. The contact may include a multilayered structure, in which the portion proximate to the semiconductor body 111 and the portion in contact with the semiconductor body 111 may include metal silicide to reduce the contact resistance and enhance the adhesion, and the portion in contact with the capacitor structure 120 may include metal to improve the performance of electrical connection.

Illustratively, the semiconductor body 111 may include, but not limited to, a semiconductor material of elementary substance (e.g., silicon, germanium), a semiconductor material of an III-V compound, a semiconductor material of an II-V compound, an organic semiconductor material or any other semiconductor material known in the art. For example, the semiconductor materials may be silicon, germanium, carbon silicide or the like. For another example, the semiconductor materials may include indium gallium zinc oxide (IGZO) or other materials. The IGZO material may include oxide of indium, gallium, zinc, etc. and has relatively good semiconductor properties. The addition of indium and gallium may increase the electron mobility of the semiconductor material, enabling a relatively low operating voltages and lower power consumption as compared with traditional semiconductor materials such as silicon; the introduction of zinc facilitates improvement of stability of the semiconductor material. The IGZO material may enable direct contact coupling between the semiconductor body 111 and the bit lines 131, the capacitor structures 120 or the metal material of other contact structures, thus reducing the contact resistance.

The gate layer 113 and the first electrode 121 may include, but not limited to, tungsten, gold, silver, platinum, copper, aluminum, titanium, nickel or any other conductive material. The bit line 131 may further include doped semiconductor materials, for example, doped silicon, in addition to the conductive materials described above, or may further include metal silicide.

The gate dielectric layer 112 may include, but not limited to, silicon oxide, silicon nitride, silicon oxynitride, aluminum oxide or other insulating material. The gate dielectric layer 112 may be the same as or similar to the dielectric material 142 filled between the adjacent semiconductor bodies 111, and may not have an obvious physical boundary.

In some examples, the memory device 10 illustrated with reference to FIG. 2 may further include a second semiconductor structure 12 including a peripheral circuit 210. The second semiconductor structure 12 and the first semiconductor structure 11 are electrically interconnected with each other through mixed bonding.

Before bonding, the first semiconductor structure 11 and the second semiconductor structure 12 may have first bonding contacts and second bonding contacts at their surfaces to be bonded respectively to fan out electrical signals of the semiconductor structures to the surfaces to be bonded respectively. The surface to be bonded of the first semiconductor structure 11 is on the side of the bit line 131 away from the capacitor structure 120 and spaced apart from the bit line 131. The bonding contacts may include pads, conductive plugs or the like. The surfaces to be bonded of the first semiconductor structure 11 and the second semiconductor structure 12 are bonded together and in contact at an interface which is referred to as a bonding interface. The first bonding contacts and the second bonding contacts are in contact with each other and bonded together at the bonding interface, enabling interconnection of electrical signals between the first semiconductor structure 11 and the second semiconductor structure 12. After bonding, the first bonding contact and the second bonding contact may have no physical boundary therebetween and may be considered as the bonding contact 133 extending through the bonding interface which is a dielectric layer. A portion of the bonding contact 133 located in the first semiconductor structure is the first bonding contact before bonding, while the portion of the bonding contact 133 located in the second semiconductor structure is the second bonding contact before bonding. The bonding contact 133 fans out the electrical signals of the first semiconductor structure 11 to the bonding interface for interconnection of electrical signals with the second semiconductor structure 12. The memory array in the first semiconductor structure 11 may be coupled to the bonding contact 133 through a wiring layer or a connection structure so as to achieve interconnection of electrical signals with the second semiconductor structure 12.

In some examples, referring to FIG. 2, the memory device 10 may further include a pad 135 that is located on the side of the first semiconductor structure 11 away from the second semiconductor structure 12 and serves as the IO interface for power supply to and communication interaction with the memory device 10. The bit lines 131, the gate layers 113, the capacitor structures 120 and the pad 135 may fan out electrical signals to the bonding interface through interconnect layers and connection structures and are coupled to the bonding contacts 133 so as to be coupled to the peripheral circuit 210 in the second semiconductor structure 12 through the bonding contacts 133. The interconnect layers may include a wiring layer, a routing layer, or a wiring layer including multiple layers that are stacked and coupled together through conductive vias or conductive plugs. The connection structures may include conductive plugs, conductive vias, or multiple conductive plugs that are stacked and coupled together.

Illustratively, the bit line 131 is coupled to the bonding contact 133 through a first connection structure 136. A plurality of capacitor structures 120 are coupled through a first interconnect layer 134, which is then coupled to the bonding contact 133 through a second connection structure 137. The first electrode 121 of the capacitor structure 120 as shown in FIG. 3 is coupled to the first interconnect layer 134. The pad 135 may be coupled to the bonding contact 133 through a third connection structure 138. The gate layer 113 may be coupled to the bonding contact 133 through another connection structure, for example, a fourth connection structure disposed on at least one end of the gate layer 113 in the y direction, so that the gate layer 113 may fan out electrical signals to the bonding contact 133 for coupling. The fourth connection structure is not shown due to the cutting direction of the cross section.

In some other examples, the second semiconductor structure 12 and the first semiconductor structure 11 may not be connected through bonding. The second semiconductor structure 12 is formed on a side of the bit lines 131 of the first semiconductor structure 11 away from the first semiconductor body 11. The bonding contacts 133 serve as conductive contacts or connection structures or there may be no bonding contacts 133 disposed.

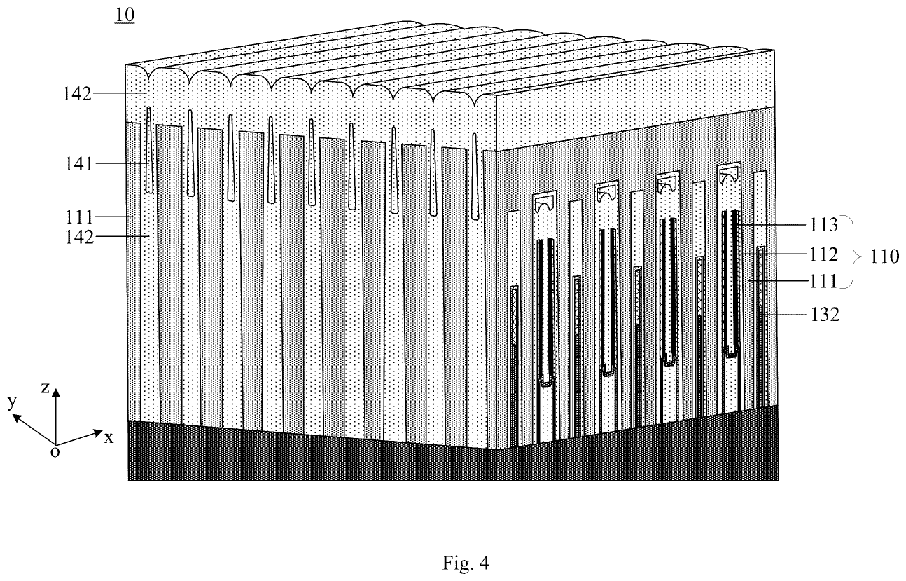

In some examples, FIG. 4 illustrates a schematic diagram of a portion of the structure in FIG. 2. As shown in FIGS. 2 and 4, the sidewalls of the first semiconductor body 111 extending in the z direction are covered or surrounded by a dielectric material 142 to reduce electrical leakage. The dielectric material 142 may have an air gap 141 at a side proximate to the first end in the z direction. During the specific fabrication process of the memory device 10, the semiconductor body 111 may be exposed to have ionic impurities and interface trap states introduced into it, causing electrical leakage. For example, during the process of forming the gate layer 113, a continuous U shape conductive material, which may include, but not limited to, metal such as tungsten, may be formed first, and then be broken through by etching to form gate layers 113 separated from each other. When etching to break through the conductive material, ionic impurities and interface trap states may be introduced into the semiconductor body 111 to cause electrical leakage from the semiconductor body 111. According to some aspects of examples of the present disclosure, the memory device 10 is provided, wherein at the first end of the semiconductor body 111 as shown in FIGS. 2 and 3, a plurality of dielectric layers are disposed to enhance the electrical isolation for the first end of the semiconductor body 111. Another dielectric layer, for example, a first dielectric layer 151, may be disposed between the dielectric material 142 surrounding the first end of the semiconductor body 111 as shown in FIGS. 2 and 3 and the first end. The first dielectric layer 151 may include a material with a high dielectric constant to enhance insulation. In some other examples, the first dielectric layer 151 may further include a negative charge or form a fixed negatively-charged layer to repel the interface charge at the first end of the semiconductor body 111 to reduce electrical leakage therefrom.

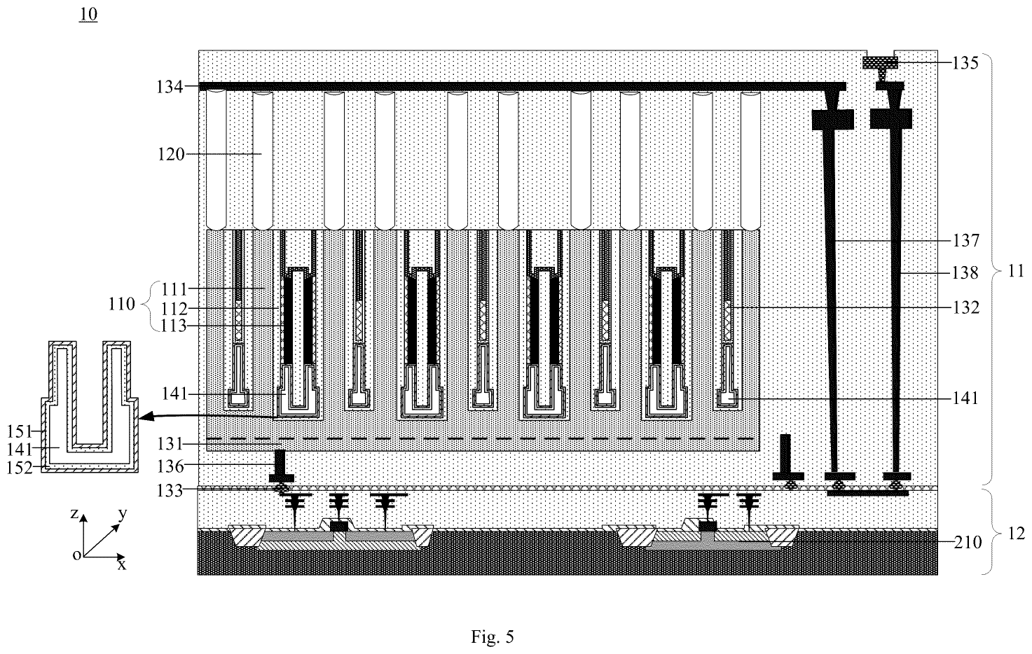

In some examples, with reference to FIG. 5, a memory device 10 is provided, the memory device 10 including: a semiconductor body 111 extending in a first direction (the z direction) and including a first end and a second end disposed opposite to each other in the z direction; a bit line 131 extending in a second direction (the x direction) and located on a side of the semiconductor body 111 proximate to the first end in the z direction and coupled to the first end of the semiconductor body 111; a first dielectric layer 151 located between at least two adjacent semiconductor bodies 111 and at least partially covering sidewalls of the first end of the semiconductor body 111 extending in the z direction, the x direction being intersecting with the z direction; and a second dielectric layer 152 located between at least two adjacent semiconductor bodies 111, wherein the first dielectric layer 151 is located between the second dielectric layer 152 and the semiconductor body 111.

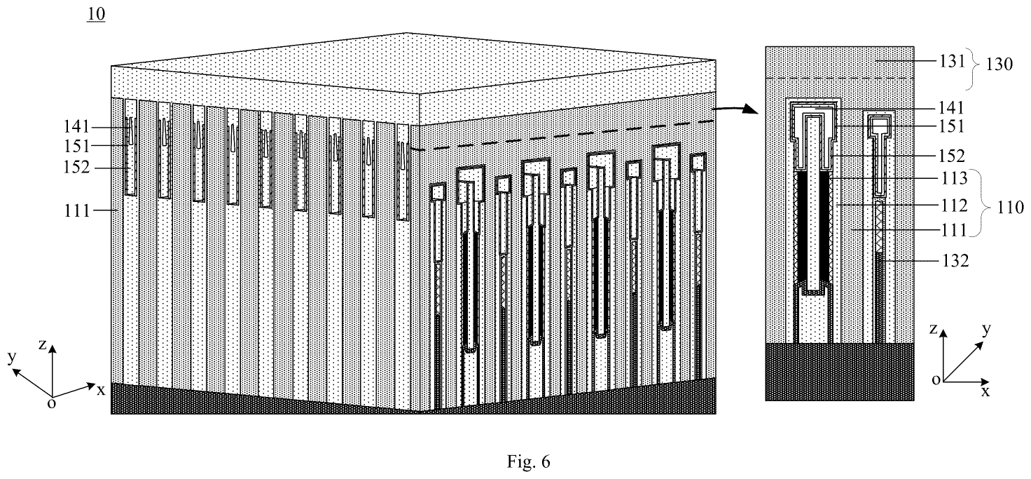

FIG. 6 may be a structural diagram of a portion of the first semiconductor structure 11 in the memory device 10 in FIG. 5. In FIG. 6, the first ends of a plurality of semiconductor bodies 111 are connected by a semiconductor material or a semiconductor strip 130. The semiconductor strip 130 is the unbroken portion of a semiconductor layer remained when the semiconductor layer is etched to form the plurality of semiconductor bodies 111. The semiconductor strip 130 extends in the x direction and may have no obvious physical boundary with the semiconductor body 111. A side of the semiconductor strip 130 away from the semiconductor body 111 in the z direction is configured to form the bit line 131 or configured to carry the bit line 131. Illustratively, in FIG. 6, the dashed line delimits the location of the bit line 131 and the portion of the semiconductor strip 130 above the dashed line serves as the bit line 131. Heavy doping may be performed based on the area of this portion of the semiconductor strip 130 to form the bit line 131, or metallization may be performed based on the semiconductor area of this portion to form metal silicide, such as titanium silicide or tungsten silicide, to form the bit line 131. The bit line 131 and the first end of the semiconductor body 111 may have no obvious physical boundary therebetween. In some other examples, a conductive material may be deposited over the semiconductor strip 130 on the side away from the semiconductor pillars to form the bit line 131. For example, tungsten may be deposited to form a metal bit line 131.

As shown in FIG. 6, the semiconductor body 111 may include a semiconductor pillar extending in the z direction, a portion of the first dielectric layer 151 may be located between any two adjacent semiconductor bodies 111 in the x direction, and the first dielectric layer 151 at least covers the sidewalls of the semiconductor body 111 extending in the z direction and may also cover the region between the adjacent semiconductor bodies 111; or there may not exist the first dielectric layer 151 between some adjacent semiconductor bodies 111 and examples of the present disclosure have no limitation on the number of the semiconductor body 111. Some portions of the first dielectric layer 151 may be located between at least two adjacent semiconductor columns in the y direction. For example, the portions of the first dielectric layer 151 extending in an xoz plane may cover the sidewalls of the semiconductor body 111 extending in the z direction. The first dielectric layer 151 may serve as a continuous three-dimensional film layer and surround the sidewalls of the first end of the semiconductor body 111 extending in the z direction. Illustratively, the shape of the cross section of the semiconductor body 111 in the xoy plane may be a rectangular shape or other quadrangle shape, or may be a regular or irregular polygon shape. Taking a rectangular shape as an example, the first dielectric layer 151 may surround 4 sidewalls of the first end of the semiconductor body 111 in the lateral direction perpendicular to the z direction.

A portion of the second dielectric layer 152 may be located between adjacent semiconductor bodies 111 in the x direction and a portion of the second dielectric layer 152 may be located between adjacent semiconductor bodies 111 in the y direction. There may not exist the second dielectric layer 152 between some adjacent semiconductor bodies 111. The second dielectric layer 152 may fill the space remaining after the first dielectric layer 151 is disposed around the sidewalls of the first ends of the adjacent semiconductor bodies 111 in the x and y directions. The first dielectric layer 151 is located between the first end of the semiconductor body 111 and the second dielectric layer 152. The second dielectric layer 152 may have air gaps to reduce the parasitic capacitance. The material constituting the first dielectric layer 151 may be a material with a high dielectric constant and may have a dielectric constant k larger than that of silicon oxide.

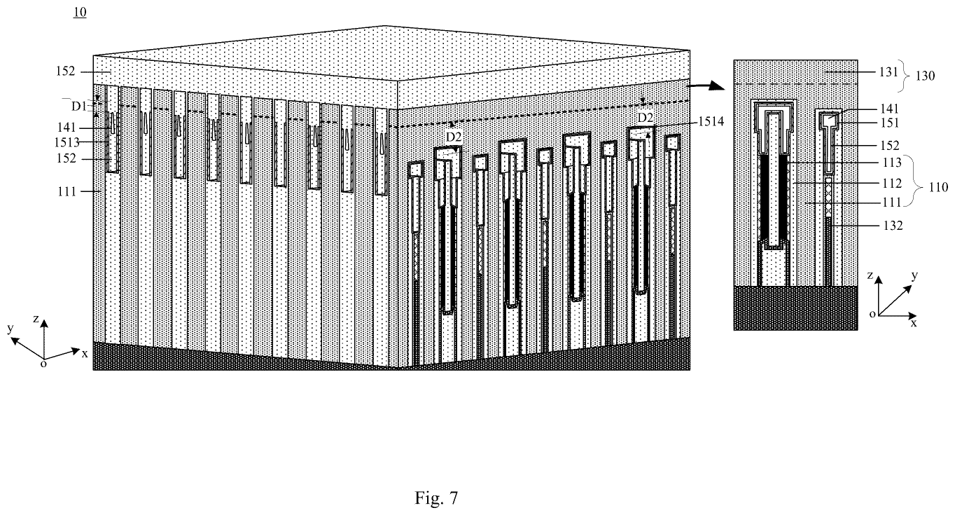

FIG. 7 may be a structural diagram of a portion of the first semiconductor structure 11 in the memory device 10 in FIG. 5. The portion of the first dielectric layer 151 between adjacent semiconductor bodies 111 in the x direction as shown in FIG. 7 may be the same as that in FIG. 6, and the portion of the first dielectric layer 151 between adjacent semiconductor bodies 111 in the y direction as shown in FIG. 7 may have a layer height lower than that in FIG. 6. The second dielectric layer 152 is configured to fill the gaps between adjacent semiconductor bodies 111 in the x/y direction to reduce electrical leakage and provide support. The portion of the second dielectric layer 152 between adjacent semiconductor bodies 111 in the x/y direction may have air gaps 141 to reduce parasitic capacitance. There is no limitation on the topography of the air gaps 141. Illustratively, the portion of the first dielectric layer 151 between adjacent semiconductor bodies 111 in the y direction as shown in FIG. 7 may extend in the xoz plane and may be spaced apart from the bit line 131, i.e. not in contact with the bit line 131. The dielectric constant between adjacent bit lines 131 in the y direction may be lowered to reduce the parasitic capacitance between the bit lines 131. The dielectric material between the first dielectric layer 151, the second dielectric layer 152, the air gap 141 and the gate layer 113 may constitute an isolation structure 150 that may have a portion extending in the x direction and a portion extending in the y direction.

In some examples, the portion of the first dielectric layer 151 covering the sidewalls of the first end of the semiconductor body 111 extending in the z direction may have a thickness in the x direction ranging from 0.1 nm to 2 nm. In some examples, the first dielectric layer 151 includes a negative charge. In some examples, the first dielectric layer 151 has a dielectric constant k larger than that of the second dielectric layer 152 and is made of a material including at least one of aluminum oxide and hafnium oxide. In some examples, the dielectric constant of the first dielectric layer 151 ranges from 5 to 40. The first dielectric layer 151 has a dielectric constant larger than the dielectric constant of the second dielectric layer to maintain relatively good electrical insulation performance while maintaining a relatively small layer thickness. The first dielectric layer 151 may also include a negative charge or form a fixed negatively-charged layer to repel the interface charge at the first end of the semiconductor body 111, thereby reducing the electrical leakage from the first end of the semiconductor body 111. The second dielectric layer 152 may include air gaps 141 to improve insulation performance while reducing parasitic capacitance.

In some examples, as shown in FIGS. 5 to 7, the memory device 10 further includes a gate layer 113 extending in a third direction (the y direction), located between at least two adjacent ones of the semiconductor bodies 111, and covering the sidewalls between the first end and second end of the semiconductor body 111 extending in the z direction, the gate layer 113 located on a side of the first dielectric layer 151 away from the bit line 131 in the first direction, wherein the y direction intersects with the x direction and a plane formed by the x direction and the y direction intersects with the z direction. The memory device 10 further includes a gate dielectric layer 112 between the gate layer 113 and the semiconductor body 111. A connection layer (such as titanium nitride) may be included between the gate dielectric layer 112 and the gate layer 113 to increase adhesion and improve the insulation performance of the gate dielectric layer 112. One transistor 110 may include one semiconductor body 111 as well as the gate dielectric layer 112 and the gate layer 113 on one sidewall of the semiconductor body 111 in the x direction. The first end and the second end of the semiconductor body 111 in the z direction are the source and the drain of the transistor 110 respectively and the area covered by the gate layer 113 serves as the channel. The material constituting the gate dielectric layer 112 may be the same as that constituting the second dielectric layer 152. Layers of the same material may not have physical boundaries therebetween when in contact.

In some examples, a portion of the first dielectric layer 151 extending in the x direction at least partially covers the gate layer 113.

In some examples, the memory device 10 further includes the conductive structures 132 each extending in the y direction and located at the end of the first dielectric layer 151 away from the bit line 131. Here, the gate layer 113 may be located between at least two adjacent conductive structures 132.

The gate layer 113 covers the intermediate area between the first end and the second end of the semiconductor body 111 and serves as the control gate of the transistor 100 to control the semiconductor body 111 on and off. The first dielectric layer 151 is located on a side of the gate layer 113 proximate to the bit line 131. The first dielectric layer 151 further includes a portion extending in the xoy plane in addition to the portion covering the sidewalls of semiconductor body 111 extending in the z direction, so as to cover the portion between the gate layer 113 and semiconductor body 111. The first dielectric layer 151 is also located at the end of the conductive structure 132 proximate to the bit line 131 and the portion of the first dielectric layer 151 extending in the xoy plane may cover the conductive structure 132. When the gate layer 113 is applied with a turn-on voltage, the conductive structure 132 may be grounded or applied with a turn-off voltage (e.g., a negative voltage) of the transistor 110 to reduce crosstalk between the transistors 110. The conductive structure 132 may include a multilayered structure, for example, a multilayered structure of titanium nitride, tungsten, polysilicon etc. to improve the electrical conductivity, reduce electrical leakage while increasing adhesion and reducing stress concentration. Examples of the present disclosure are not limited in this respect.

In some examples, the portion of the first dielectric layer 151 extending in the x direction at least partially covers the area between the two adjacent semiconductor bodies 111.

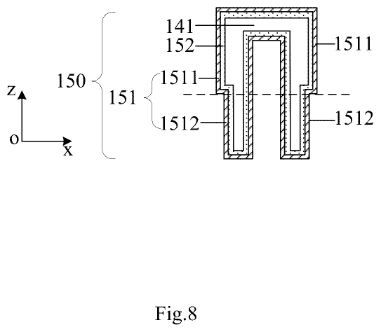

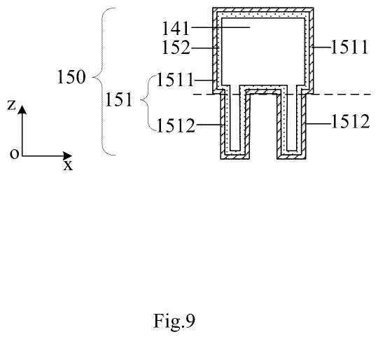

In some examples, with reference to FIGS. 6 and 7, the memory device 10 further includes a semiconductor strip 130 extending in the x direction, located between the bit line 131 and the semiconductor body 111 and connected with the first end of the semiconductor body 111. With reference to FIGS. 8 and 9, the first dielectric layer 151 includes: a first portion 1511 that at least partially covers the sidewalls of the first end of the semiconductor body 111 extending in the z direction and at least partially covers the area of the semiconductor strip 130 between two adjacent semiconductor bodies 111; and a second portion 1512 protruding from the first portion 1511 towards the gate layer 113 in the z direction, wherein the portion of the second portion 1512 extending in the x direction at least partially covers the gate layer 113.

In some examples, the cross section of the first dielectric layer 151 in a first plane has a shape of closed figure with the first plane being a plane formed by the z direction and the y direction, for example, the xoz plane. The closed figure includes at least one of straight lines or arcs.

With reference to FIG. 6, the semiconductor strip 130 is the unbroken portion of a semiconductor layer remained when the semiconductor layer is etched to form a plurality of semiconductor bodies 111. The semiconductor strip 130 extends in the x direction and may have no obvious physical boundary with the semiconductor body 111. The side of the semiconductor strip 130 away from the semiconductor body 111 in the z direction is configured to form the bit line 131 or configured to carry the bit line 131. Metal silicide may be formed as the bit line 131 based on the semiconductor strip 130, or a metal layer may be deposited on the semiconductor layer to form the bit line 131. The first dielectric layer 151 may have a portion extending in the xoy plane to cover the area of the semiconductor strip 130 between the semiconductor bodies 111, thereby reducing electrical leakage from the semiconductor strip 130. The first dielectric layer 151 may totally or partially cover the area of the semiconductor strip 130 between the semiconductor bodies 111.

In some other examples, when the semiconductor layer is etched to form the semiconductor body 111, the semiconductor layer may be broken or penetrated through, so that the adjacent semiconductor bodies 111 in the x direction have no semiconductor material left therebetween and may have a dielectric material disposed therebetween as a spacer. The dielectric material may be the same as that of the second dielectric layer 152 and may be silicon oxide or a spin-coated insulation dielectric. The portion of the first dielectric layer 151 extending in the xoy plane in this example covers the dielectric material between the semiconductor bodies 111 along the z direction. A conductive material is deposited on the side of the semiconductor body 111 proximate to the first end to form the bit line 131.

In some examples, the enlarged view of the cross-sectional structure in the xoz plane of the first dielectric layer 151 and the second dielectric layer 152 in FIGS. 6 and 7 is illustrated in FIG. 8. In FIG. 8, an upper portion of the first dielectric layer 151 is the first portion 1511 covering the sidewalls of the first end of the semiconductor body 111 extending in the z direction, and a lower portion is the second portion 1512 protruding and extending towards the gate layer 113. The dimension of the second portion 1512 in the x direction is smaller than the dimension of the first portion 1511 in the x direction. The two sidewalls of the first portion 1511 extending in the z direction cover the first ends of two semiconductor bodies 111. An upper wall of the first portion 1511 extending in the x direction covers the area between the first ends of the two adjacent semiconductor bodies 111, for example, the area of the semiconductor strip 130 between the first ends of the two adjacent semiconductor bodies 111. A lower wall of the first portion 1511 extending in the x direction and being shorter than the upper wall covers the gate dielectric layer 112. The sidewalls of second portion 1512 extending in the z direction are in contact with gate dielectric layer 112 and a lower wall of the second portion 1512 extending in the x direction is in contact with and covers the gate layer 113.

In FIG. 8, the topography of the first portion 1511 of the first dielectric layer 151 has an n shape or an inverted u shape. In another example, the first portion 1511 of the first dielectric layer 151 shown in FIG. 9 may have a rectangular shape or other quadrangle shape. The cross section of the first dielectric layer 151 in the xoz plane as shown in FIGS. 8 and 9 may have a shape of closed figure, whose edges may be straight lines or arcs. For example, there may be an arc at a corner where the two straight lines connect. This may be because the materials remained during an etching process form an arced layer landing surface. The second dielectric layer 152 may be formed through deposition on the first dielectric layer 151 based on the topography of the first dielectric layer 151 and may have the same shape as the first dielectric layer 151. The space enclosed by the second dielectric layer 152 may be an air gap 141 or a cavity without any dielectric material filled therein.

In some examples, the first dielectric layer 151 in FIGS. 8 and 9 may not have any portion extending in the x direction and covering the area between the semiconductor bodies 111, or may not have any second portion 1512 extending towards the gate layer 113, instead, it only has a portion covering the sidewalls of the first end of the semiconductor body 111 extending in the z direction to form an unclosed figure. Alternatively, there may be a notch at any edge of the closed figure, leading to a topography of the unclosed figure.

In some examples, with reference to FIG. 7, the first dielectric layer 151 includes a third portion 1513 located between at least two adjacent semiconductor bodies 111 in the y direction and extending in a second plane formed by the z direction and the x direction, for example, the xoz plane. The third portion 1513 at least partially covers the sidewalls of the first end of the semiconductor body 111 extending in the z direction. Here, the y direction intersects with the x direction and the plane formed by the x direction and the y direction intersects with the z direction. The third portion 1513 of the first dielectric layer 151 may be an unclosed figure and have an opening at the side proximate to the bit line 131. The third portion 1513 of the first dielectric layer 151 may have portions extending in the z direction to cover sidewalls of the semiconductor body 111 and portions extending in the y direction to connect the portions covering the sidewalls of the semiconductor body 111. The third portion 1513 of the first dielectric layer 151 has a cross section of a U shape in the yoz plane.

In some examples, with reference to FIG. 7, the bit line 131 is located at an end of the third portion 1513 of the first dielectric layer 151 in the first direction and the third portion 1513 is spaced apart from the bit line 131 in the first direction. The third portion 1513 of the first dielectric layer 151 between adjacent semiconductor bodies 111 in the y direction may be spaced apart from the bit line 131 or the pre-formation location of the bit line 131, i.e. not in contact with the bit line 131 or not overlapping with the bit line 131 in the y direction, so that the parasitic capacitance between the bit lines 131 may be reduced by lowering the dielectric constant between the adjacent bit lines 131 in the y direction.

In some examples, with reference to FIG. 7, the first dielectric layer 151 may further include a fourth portion 1514 located between at least two adjacent semiconductor bodies 111 in the x direction. An end of the third portion 1513 of the first dielectric layer 151 proximate to the bit line 131 in the z direction has a first distance D1 from the bit line 131, an end of the fourth portion 1514 proximate to the bit line 131 in the first direction has a second distance D2 from the bit line 131, and the first distance D1 is smaller than or equal to the second distance D2. The cross-sectional structure of the fourth portion 1514 of the first dielectric layer 151 in the xoz plane may be as shown in FIG. 8 or 9, or the fourth portion 1514 of the first dielectric layer 151 may at least include the portions extending in the z direction in FIG. 8 or 9 and at least cover the sidewalls of the semiconductor body 111 extending in the z direction. Taking the case, in which the portion of the first dielectric layer 151 covering the sidewalls of the first end of the semiconductor body 111 is the fourth portion 1514, as an example, the fourth portion 1514 has the second distance D2 from the bit line 131 or the pre-formation location of the bit line 131, the second distance D2 being larger than the first distance D1. Therefore, the third portion 1513 of the first dielectric layer 151 is nearer to the bit line 131 as compared to the fourth portion 1514 and the third portion 1513 in FIG. 7 has a layer height larger than that of the fourth portion 1514, which may reduce the loss of the fourth portion 1514 during the fabrication process, facilitate to maintain a relatively large area of the semiconductor body 111 covered by the first dielectric layer 151, and reduce the electrical leakage from the first end of the semiconductor body 111.

In some examples, with reference to FIGS. 8 and 9, the memory device 10 further includes an isolation structure 150 located between at least two adjacent semiconductor bodies 111, wherein the isolation structure 150 includes a first dielectric layer 151, a second dielectric layer 152 and an air gap 141 enclosed by the second dielectric layer 152 with the air gap 141 being proximate to the bit line 131 in the z direction. The first dielectric layer 151, the second dielectric layer 152 and the air gap 141 may constitute at least a portion of the isolation structure 150, which may further include a dielectric material between the gate layers 113 and other dielectric materials between the adjacent semiconductor bodies 111; the isolation structure 150 may have portions extending in the x direction and portions extending in the y direction.

In some examples, the capacitor structure 120 may be disposed on the side of the structure shown in FIGS. 6 and 7 away from the bit line 131 and coupled to the second end of the semiconductor body 111 away from the bit line 131.

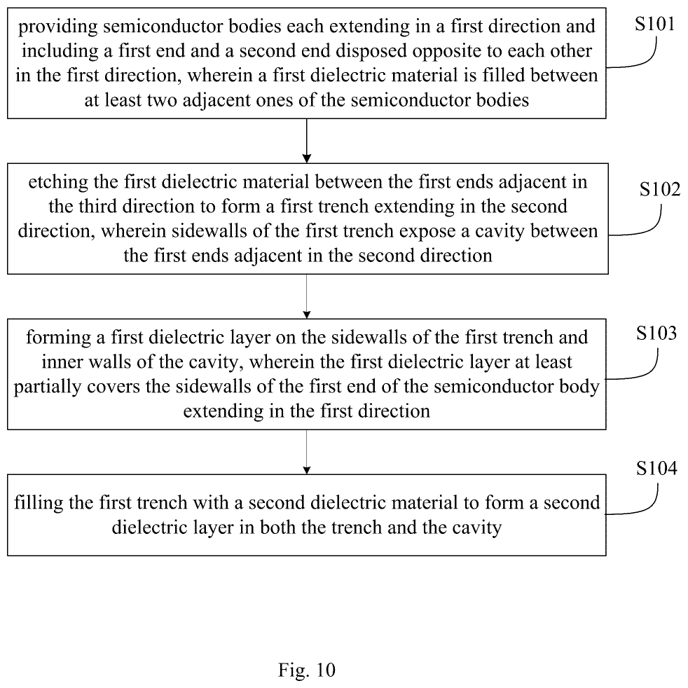

According to some aspects of examples of the present disclosure, FIG. 10 provides a fabrication method of a memory device 10, including: providing semiconductor bodies each extending in a first direction (the z direction) and including a first end and a second end disposed opposite to each other in the first direction, with a first dielectric material filled between at least two adjacent ones of the semiconductor bodies, a second direction (the x direction) intersecting with the first direction, a third direction (the y direction) intersecting with the second direction, and a plane formed by the second direction and the third direction intersecting with the first direction; etching the first dielectric material between the first ends adjacent in the third direction to form a first trench extending in the second direction, sidewalls of the first trench exposing a cavity between the first ends adjacent in the second direction; forming a first dielectric layer on the sidewalls of the first trench and inner walls of the cavity, the first dielectric layer at least partially covering sidewalls of the first end of the semiconductor body extending in the first direction; and filling the first trench with a second dielectric material to form a second dielectric layer in both the trench and the cavity.

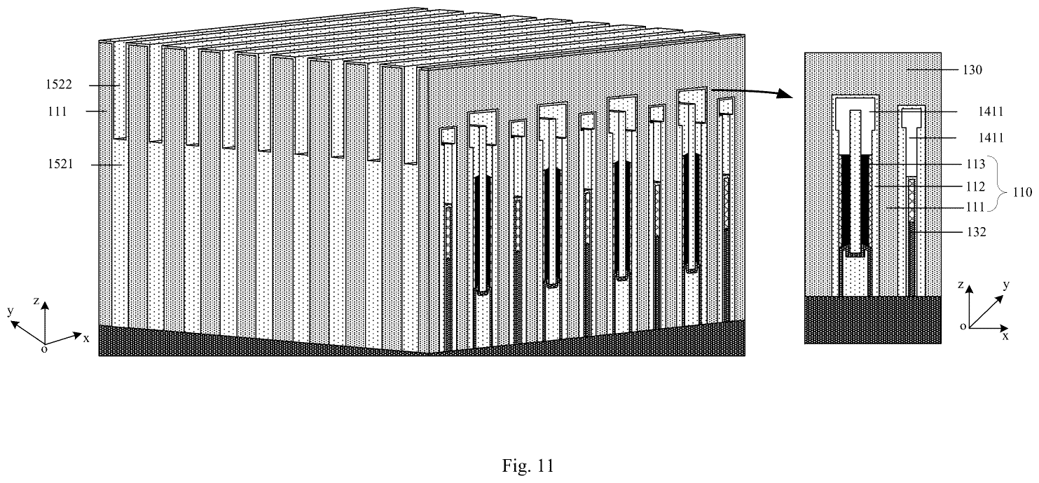

With reference to FIG. 11, a plurality of semiconductor bodies 111 arranged in the x direction and a plurality of semiconductor bodies 111 arranged in the y direction are provided to form an array of semiconductor bodies 111. The semiconductor body 111 has a first end and a second end disposed opposite to each other in the z direction. The first end of the semiconductor body 111 is connected with a semiconductor strip 130, which is configured to form or carry the bit line 131. The first end of the semiconductor body 111 in FIG. 11 is the top. The material of the semiconductor strip 130 may be the same as that of the semiconductor body 111 and there may be no physical boundary therebetween. The gate layer 113 extending in the y direction is disposed between adjacent semiconductor bodies 111 and covers the sidewalls of the area between the first end and the second end of the semiconductor body 111. The gate dielectric layer 112 is disposed between the gate layer 113 and the semiconductor body 111. The conductive structure 132 may be disposed between adjacent semiconductor bodies 111 to reduce crosstalk between adjacent gate layers 113. The first dielectric material 1521 is filled between adjacent semiconductor bodies 111. The cavity 1411 is provided at a first end of the first dielectric material 1521 proximate to the semiconductor body 111, or at the top of the first dielectric material 1521 in FIG. 11. The cavity 1411 is on a side of the gate layer 113 proximate to the first end of semiconductor body 111, and also on a side of the conductive structure 132 proximate to the first end of the semiconductor body 111.

With reference to FIG. 11, the first dielectric material 1521 between the first ends of the semiconductor bodies 111 adjacent in the y direction is etched to form a first trench 1522 extending in the x direction. The sidewalls of the first trench 1522 may expose at least part of the cavity 1411. The first trench 1522 communicates with the cavity 1411. FIG. 11 further shows a partially enlarged diagram of the structure having the cavity 1411.

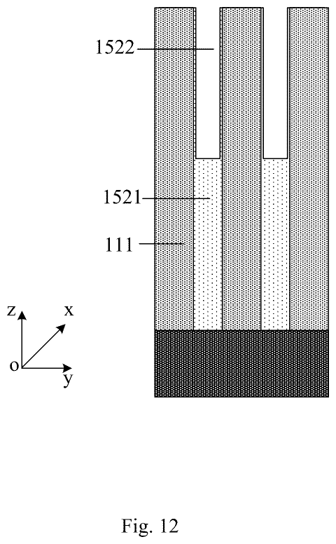

The cross-sectional diagram of the first trench 1522 in the yoz plane may be as shown in FIG. 12. During the process of etching the first trench 1522, etchant may enter the cavity 1411 to etch its inner walls and thus enlarge the cavity 1411, or after etching of the first trench 1522, the cavity 1411 is or is not enlarged. The sidewalls of the first trench 1522 may be provided by the semiconductor body 111 or the first dielectric material 1521. When forming the first trench 1522, part of the first dielectric material 1521 is left to cover the sidewalls of the semiconductor body 111 and thus reduce oxidation and over-etching damages to the semiconductor body 111. The etching process may include, but not limited to, dry etching, wet etching or a combination thereof.

The process of forming the first dielectric layer 151 may include a deposition process that may include, but not limited to, chemical vapor deposition (CVD), physical vapor deposition (PVD) and atomic layer deposition (ALD). The process of filling up the remaining space of the first trench 1522 may include a deposition process or a dielectric spin-coating process.

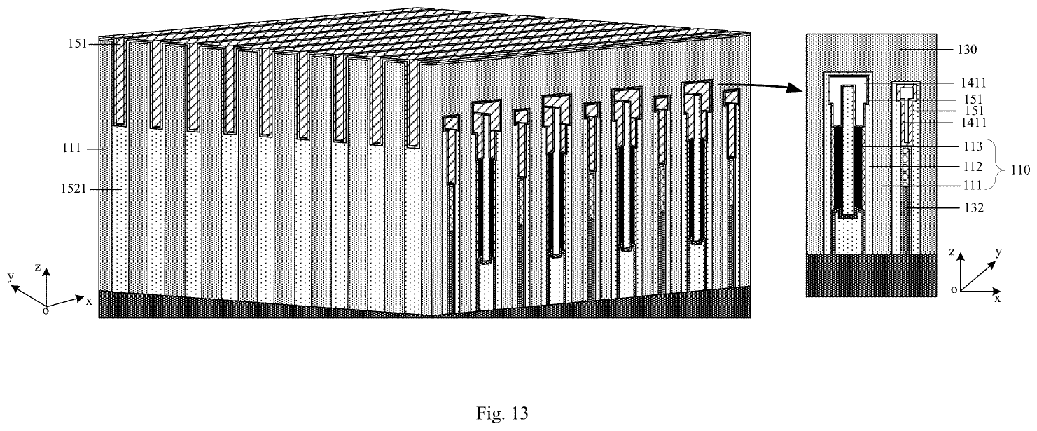

With reference to FIG. 13, the first dielectric layer 151 may be formed on the sidewalls and bottom of the first trench 1522 and on the inner walls of the cavity 1411. The first dielectric layer 151 may be formed in the same deposition process including atomic layer deposition. It is to be noted that the first trench 1522 in FIG. 13 is not filled up by the first dielectric layer 151 and the first dielectric layer 151 on the inner walls of the first trench 1522 is shown due to the view angle. A portion of the first dielectric layer 151 may be formed on the inner walls of the cavity 1411 on the top of the conductive structure 132.

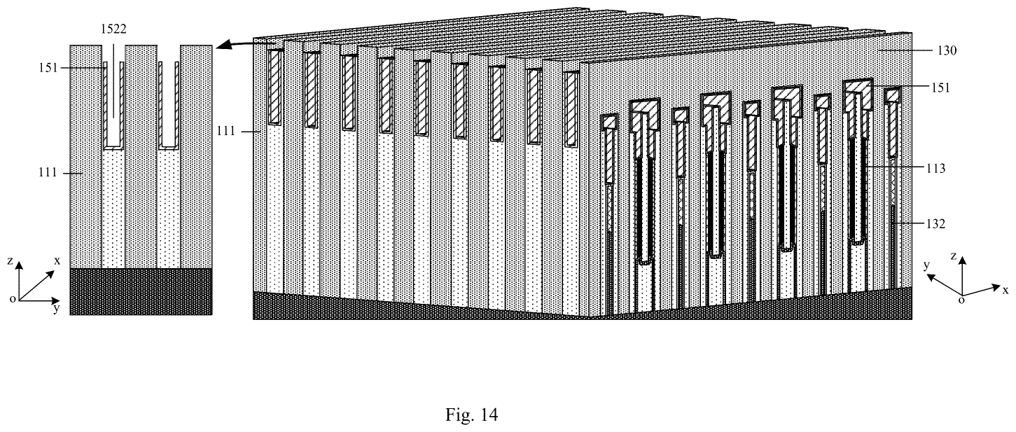

With reference to FIG. 14, a portion of the first dielectric layer 151 on the sidewalls of the second trench 1531 is removed by etching to reduce the layer height of the first dielectric layer 151. Alternatively, a portion of the first dielectric layer 151 on the bottom of the second trench 1531 may also be removed by etching or may not be removed.

In some examples, with reference to FIG. 14, the fabrication method may further include penetrating through the first dielectric layer 151 on the bottom of the first trench 1522 in the z direction.

In some examples, with reference to FIG. 13, the cross section of the first dielectric layer 151 in a first plane has a shape of closed figure with the first plane being the xoz plane formed by the z direction and the x direction. The closed figure includes at least one of straight lines or arcs. The first dielectric layer 151 covering the inner walls of the cavity 1411 shown in FIG. 13 has a shape of closed figure in the xoz plane, which may be enclosed by straight lines and arcs, and some material residues forming the arcs may exist at some corners of cavity 1411, and form an arc topography of the first dielectric layer 151 after being covered by the dielectric material. In some other examples, when a portion of the first dielectric layer 151 is removed by etching as shown in FIG. 14, part of the etchant may enter the cavity 1411 to etch the portion of the first dielectric layer 151 over the top inner wall of the cavity 1411, so that the first dielectric layer 151 is formed to have a topography of an unclosed figure.

In some examples, the fabrication method further includes: forming the bit line 131 extending in the x direction on the side of the semiconductor body 111 proximate to the first end, the bit line 131 coupled to the first end of the semiconductor body 111.

In some examples, the first end of the semiconductor body 111 is connected with the semiconductor strip 130 and the first trench 1522 is located between adjacent semiconductor strips 130; the method of forming the bit line 131 includes: forming the bit line 131 based on the semiconductor strip 130, with at least a portion of the bit line 131 located in the semiconductor strip 130 and the bit line 131 located over the first dielectric layer 151.

In some examples, the bit line 131 is formed on the side of the semiconductor strip 130 away from the gate layer 113 in FIGS. 11, 13 and 14, and coupled to the first end of the semiconductor body 111. Illustratively, a metal material is deposited on, or a gas containing a metal element is introduced into, the side of the semiconductor strip 130 away from the gate layer 113, and a thermal treatment is performed to the semiconductor strip 130. A portion of the semiconductor strip 130 reacts with the metal element to form a metal-semiconductor compound as the bit line 131, which may be, for example, tungsten silicide or titanium silicide. Thereby, the increment in the dimension in the z direction caused otherwise by additional deposition of the bit line 131 may be reduced. The location in the semiconductor strip 130, where the bit line 131 is formed, may be as illustrated in FIG. 6. In some other examples, the bit line 131 may be formed by depositing a conductive material on the side of the semiconductor strip 130 away from the gate layer 113. The conductive material may include, but not limited to, tungsten, gold, silver, platinum, copper, aluminum, titanium, nickel or the like. In some other examples, the semiconductor strip 130 may be penetrate through in the z direction, so that no semiconductor material connection would exist between the semiconductor bodies 111, and the bit line 131 may be formed by depositing a conductive material on the first end of the semiconductor body 111. Examples of the present disclosure does not limit the formation sequence and process node of the bit line 131. The bit lines 131 may be formed at the process node of exposing the semiconductor strip 130, thus reducing the fabrication cost.

In some examples, with reference to FIG. 6, a portion of the space within the first trench 1522 shown in FIG. 14 is filled with a second dielectric material and a portion of the space within the cavity 1411 is filled with the second dielectric material, to form the second dielectric layer 152 with an air gap 141.

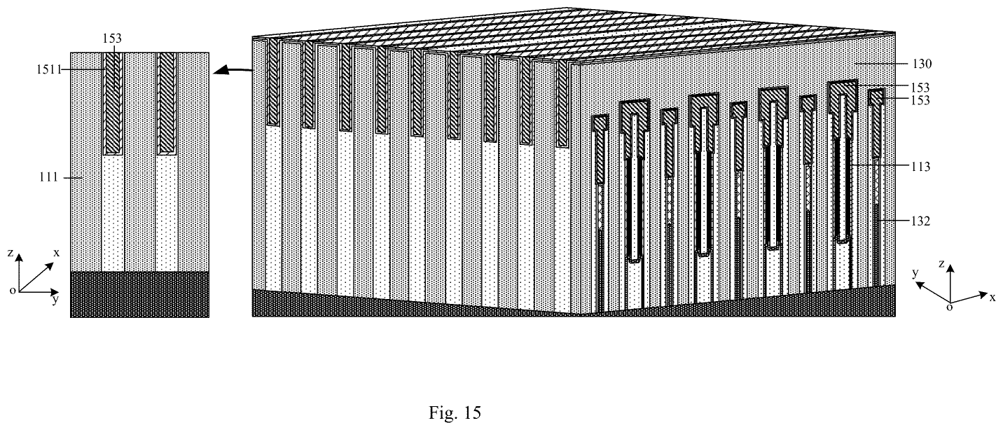

In some examples, the fabrication method further includes: with reference to FIG. 15, forming the first dielectric material layer 1511 on the sidewalls of the first trench 1522 and the inner walls of the cavity 1411 in FIG. 11; filling the first trench 1522 and the cavity 1411 to form a sacrificial structure 153;

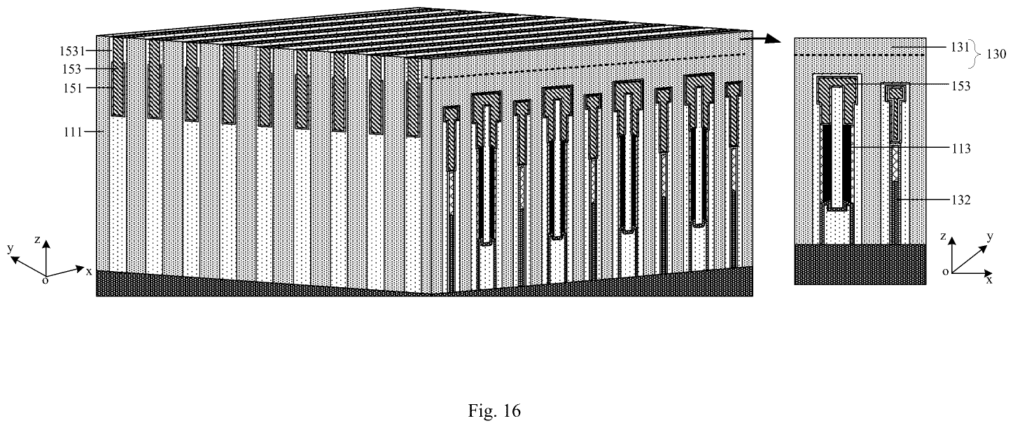

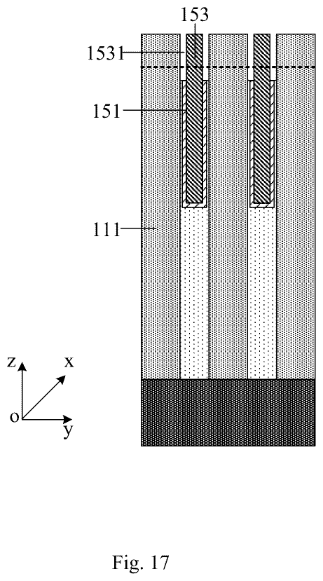

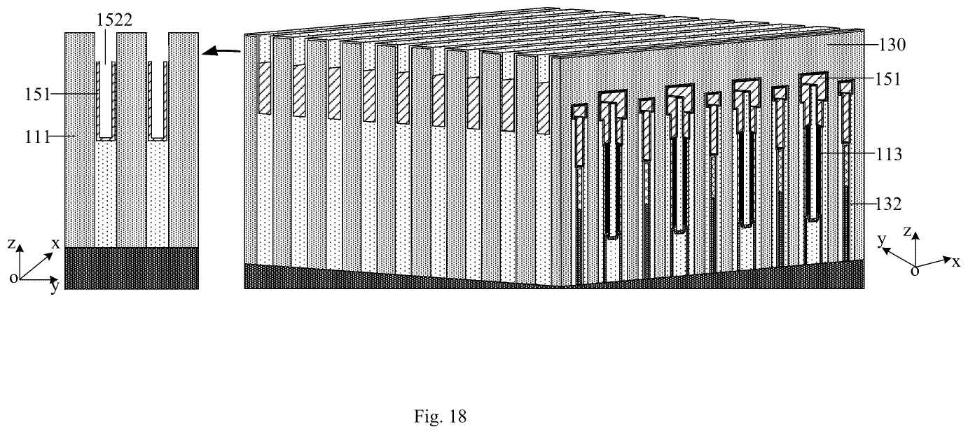

with reference to FIGS. 16 and 17, etching the first dielectric material layer 1511 in the first trench 1522 to lower the height of the top surface of the first dielectric material layer 1511 in the first trench 1522 in the z direction and thus form the first dielectric layer 151; and
with reference to FIG. 18, removing the sacrificial structure 153 and forming the second dielectric layer 152.

In FIG. 15, the sacrificial structure 153 fills up the remaining space of the first trench 1522 having the first dielectric material layer 1511 and also the remaining space of the cavity 1411 having the first dielectric material layer 1511, and the first trench 1522 does not communicate with the cavity 1411 at this point. In FIG. 16, when the first dielectric material layer 1511 on the sidewalls of the first trench 1522 is removed by etching, the etching is controlled to stop at a position above the top inner wall of the cavity 1411, so that the first dielectric layer 151 in the cavity 1411 can be prevented from being etched by the etchant.

In some examples, with reference to FIG. 16, the fabrication method includes: etching the first dielectric material layer 1511 to form a second trench 1531 extending in the x direction, wherein the bottom of the second trench 1531 is over or flush with the top inner wall of the cavity 1411. The second trench 1531 extends in the x direction. In the example shown in FIG. 17, the bottom of the second trench 1531 is higher than the top inner wall of the cavity 1411 and due to the isolation by the sacrificial structure 153, the first dielectric material layer 1511 in the cavity 1411 will not be exposed by the second trench 1531, so that the first dielectric material layer 1511 in the cavity 1411 is prevented from being etched.

In some examples, the fabrication method further includes: forming the bit line 131 on the side of the semiconductor strip 130 away from the gate layer 113 in FIG. 15 or 16, the bit line 131 coupled to the first end of the semiconductor body 111; with reference to FIG. 18, removing the sacrificial structure 153 in the first trench 1522 to release the space within the first trench 1522; and, with reference to FIG. 7, filling a portion of the space of the first trench 1522 with the second dielectric material and filling a portion of the space of the cavity 1411 with the second dielectric material to form the second dielectric layer 152 enclosing an air gap 141. As shown in FIGS. 16 and 17, there is no limitation on the forming order of the bit line 131 and the second trench 1531. The bottom of the second trench 1531 may be located between the bit line 131 or the pre-formation location of the bit line 131 and the first dielectric layer 151 at the top of the cavity 1411, so that the first dielectric layer 151 does not cover the bit line 131 to reduce parasitic capacitance between the bit lines 131 and reduce etching of the first dielectric layer 151 in the cavity 1411 by the etchant through the second trench 1531.

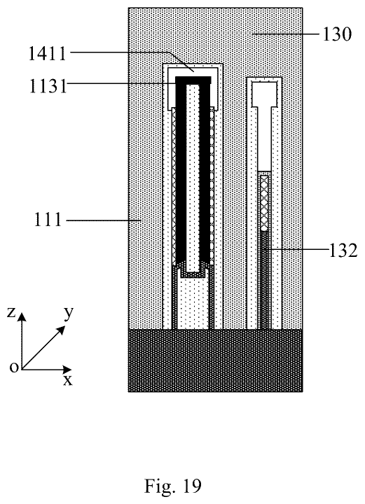

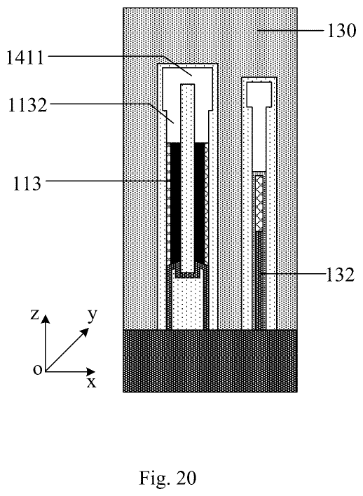

In some examples, with reference to FIG. 19, the cavity 1411 exposes a conductive material layer 1131 that is between adjacent semiconductor bodies 111, the conductive material layer 1131 at least partially covering the sidewalls of the semiconductor body 111 extending in the z direction. The fabrication method further includes: with reference to FIG. 20, etching the portion of the conductive material layer 1131 exposed from the cavity 1411 through the first trench 1522 to penetrate through, in the z direction, the portion of the conductive material layer 1131 extending in the x direction and thus form the gate layer 113; continuing to etch the gate layer 113 to reduce the dimension of the gate layer 113, so that the middle portion of the gate layer 113 located at the sidewalls of the semiconductor body 111 corresponds to the channel; and subsequently forming the first dielectric layer 151 on the gate layer 113, the portion of the first dielectric layer 151 extending in the x direction at least partially covering the gate layer 113.

In some examples, with reference to FIG. 20, the gate layer 113 is etched along the z direction to reduce the dimension of the gate layer 113 in the z direction to form the topography of the gate layer 113 as shown in FIG. 11, so that the third trench 1132 extending in the y direction is formed on the gate layer 113 and communicates with the cavity 1411; subsequently the first dielectric layer 151 is formed on the inner walls of the cavity 1411 and the inner walls of the third trench 1132. The first dielectric layer 151 may be as shown in FIG. 8 and have the first portion 1511 and the second portion 1512. The first portion 1511 is formed on the inner walls of the cavity 1411 and the second portion 1512 is formed on the inner walls of the third trench 1132. The portion of the second portion 1512 extending in the x direction covers the gate layer 113.

In some examples, when the conductive material layer 1131 is broken by etching to form the gate layers 113 separated from each other, metal ions or interface trap states may be introduced into the semiconductor body 111, causing electrical leakage from the semiconductor body 111. The first dielectric layer 151 is formed to at least partially cover the sidewalls of the first end of the semiconductor body 111 extending in the z direction and the first dielectric layer 151 may have a dielectric material with a high dielectric constant to improve insulation performance and reduce electrical leakage. The first dielectric layer 151 may further include a negative charge or form a fixed negatively-charged layer to repel the interface charge at the first end of the semiconductor body 111 and reduce electrical leakage therefrom.

In some examples, the portion of the second dielectric layer 152 away from the gate layer 113 in FIGS. 6 and 7 is removed to expose the bit line 131, and the second semiconductor structure 12 is bonded on the side of the bit line 131 away from the gate layer 113. The peripheral circuit 210 in the second semiconductor structure 12 is coupled to the bit line 131 through the bonding contacts 133. The carrier wafer or substrate on the side of the semiconductor body 111 away from the bit line 131 is removed to expose the second end of the semiconductor body 111. The capacitor structure 120 is formed on the second end to be coupled to the semiconductor body 111. Pads 135 and other structures are formed on the side of the capacitor structures 120 away from the semiconductor body 111. As a result, the memory device 10 as shown in FIG. 5 is formed.

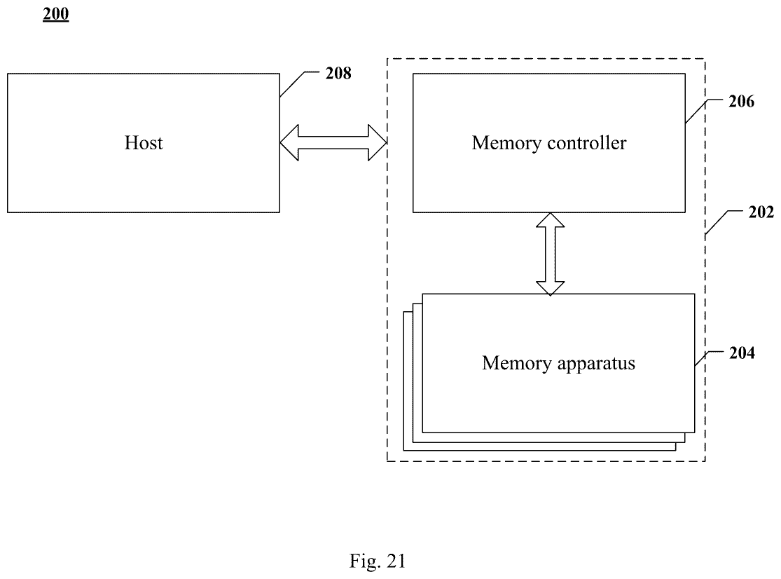

According to some aspects of examples of the present disclosure, a memory system 202 is provided, the memory system including the memory device 10 as illustrated in FIGS. 2 to 7 and a memory controller 206 coupled to and controlling the memory device 10. FIG. 21 provides a memory system 202 including a memory apparatus 204 and a memory controller 206 coupled to and controlling the memory apparatus 204. The memory apparatus 204 includes the memory device 10 illustrated in FIGS. 2 to 7. The memory device 10 is the memory apparatus 204 or at least a part of the memory apparatus 204.

As shown in FIG. 21, examples of the present disclosure provide a system 200 including a host 208. The system 200 may be a mobile phone, a graphic processing apparatus, a desktop computer, a laptop computer, a tablet computer, a vehicle computer, a game console, a printer, a position device, a wearable electronic device, a smart sensor, a virtual reality (VR) device, an augmented reality (AR) device and any other suitable electronic device having a storage therein. As shown in FIG. 21, the system 200 may include a host 208 and a memory system 202 that has one or more memory apparatuses 204 and a memory controller 206. The host 208 can be a processor of an electronic device such as a central processing unit (CPU), or a system-on-chip (SoC) such as an application processor (AP). The host 208 may be configured to send data to the memory apparatus 204 or receive data from the memory apparatus 204. The memory apparatus 204 may include the memory device 10 as shown in FIGS. 2 to 7.

According to some examples, the memory controller 206 is coupled to the memory apparatus 204 and the host 208 and configured to control the memory apparatus 204 to perform read, write or refresh operations. The memory controller 206 can manage the data stored in the memory device 204 and communicate with the host 208. The memory apparatus 204 may include a DRAM or a package body structure formed by a plurality of stacked DRAMs, which can be applied to an HBM or HMC package structure.

In some specific examples, an HBM package structure may include a plurality of DRAM chips stacked vertically on a logic chip. The logic chip may communicate electrical signals with the plurality of DRAM chips through TSVs. The plurality of DRAM chips and the logic chip may serve as a memory system. The logic chip may include, but not limited to, a control logic, an interface control module, an SRAM cache or other components and may be configured as the memory controller 206. The memory device 10 shown in FIGS. 2 to 7 may be configured as the memory apparatus 204. The HBM package structure may further include a GPU chip, a CPU chip, an SOC chip or another processor chip. An internal memory controller may be integrated in a processor to control data transmission of the DRAM chips. Illustratively, the GUP or other processors are coupled to the logic chip and perform data interactions with the DRAMs through the logic chip. In some other specific examples, a hybrid memory cube (HMC) package structure may include a plurality of DRAM chips stacked vertically on a logic chip. The logic chip communicates electrical signals with the plurality of DRAM chips through TSVs. The plurality of DRAM chips and the logic chip may serve as a memory system. The logic chip may include, but not limited to, a control logic, an interface control module, an SRAM cache or other components and may have an internal controller integrated therein.

In some specific examples, the memory system 202 can be used for assistance in a solid-state drive to improve performance of the solid-state drive in writing/reading or other aspects. Nowadays, embedded DRAMs are usually chosen for high-end products to improve their product performance and speed of random reading/writing. Illustratively, when a file, especially a small file, is being written, it is processed through a DRAM and then stored in a flash to enable the solid-state drive to have higher efficiency and speed of storage. The flash includes a nonvolatile memory including, but not limited to, a 2D NAND memory or a 3D NAND memory. In some specific examples, the memory system 202 may be used in a graphics processing device as the cache device of its graphics processing unit. The graphics processing device may include, but not limited to, a graphics card.

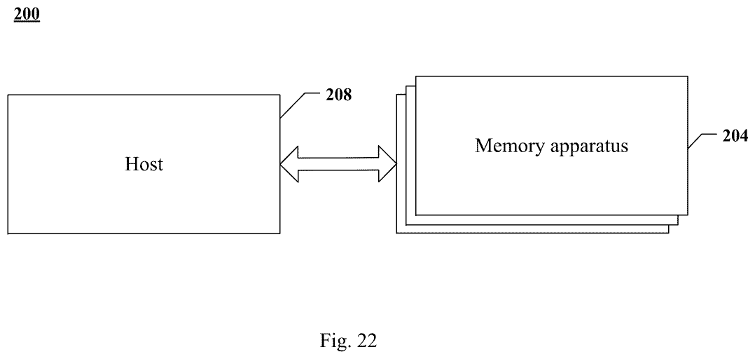

In some other examples, with reference to FIG. 22, the system 200 may only include a host 208 and a memory apparatus 204 coupled to the host 208. The controller for controlling the memory apparatus 204 may be located inside the host 208, for example, an internal memory controller integrated in a CPU or a south bridge or north bridge chip integrated in the mainboard of the system 200. The memory apparatus 204 may include, but not limited to, a double data rate synchronous dynamic random access memory using DDR4 and DDR5 memory specifications, a low power consumption double data rate synchronous dynamic random access memory using DDR5 memory specification. The memory apparatus 204 may include the memory device 10 shown in FIGS. 2 to 7.

What have been described above are only specific implementations of the present disclosure. However, the scope of the present disclosure is not limited thereto, and variations or substitutions that easily occur to those skilled in the art in light of the technical contents disclosed by the present disclosure will fall within the scope of the present disclosure.

What is claimed is:

1. A memory device, comprising:
semiconductor bodies each extending in a first direction, a semiconductor body comprising a first end and a second end disposed opposite to each other in the first direction;
a bit line extending in a second direction intersecting the first direction, the bit line being located on a side of the semiconductor body proximate to the first end of the semiconductor body in the first direction and coupled to the first end of the semiconductor body;
a first dielectric layer located between at least two adjacent ones of the semiconductor bodies comprising the semiconductor body, the first dielectric layer at least partially covering sidewalls of the first end of the semiconductor body extending in the first direction; and
a second dielectric layer located between the at least two adjacent ones of the semiconductor bodies, wherein the first dielectric layer is located between the second dielectric layer and the semiconductor body.

2. The memory device of claim 1, further comprising:
a gate layer extending in a third direction, located between the at least two adjacent ones of the semiconductor bodies, covering sidewalls between the first end and the second end of the semiconductor body extending in the first direction, and being located on a side of the first dielectric layer away from the bit line in the first direction,
wherein the third direction intersects with the second direction and a plane formed by the second direction and the third direction intersects with the first direction.

3. The memory device of claim 2, wherein a portion of the first dielectric layer extending in the second direction at least partially covers the gate layer.

4. The memory device of claim 2, further comprising:
conductive structures each extending in the third direction and located at an end of the first dielectric layer away from the bit line, wherein the gate layer is located between at least two adjacent ones of the conductive structures.

5. The memory device of claim 2, further comprising:
a semiconductor strip extending in the second direction, the semiconductor strip being located between the bit line and the semiconductor body and connected to the first end of the semiconductor body,
wherein the first dielectric layer comprises:
a first portion at least partially covering the sidewalls of the first end of the semiconductor body extending in the first direction and at least partially covering an area of the semiconductor strip between two adjacent ones of the semiconductor bodies; and
a second portion protruding from the first portion towards the gate layer in the first direction, wherein a portion of the second portion extending in the second direction at least partially covers the gate layer.

6. The memory device of claim 1, wherein a portion of the first dielectric layer extending in the second direction at least partially covers an area between two adjacent ones of the semiconductor bodies.

7. The memory device of claim 1, wherein a cross section of the first dielectric layer in a first plane has a shape of closed figure, the first plane being a plane formed by the first direction and the second direction, and the closed figure comprises at least one of straight lines or arcs.

8. The memory device of claim 1, wherein the first dielectric layer comprises:
a third portion being located between at least two adjacent semiconductor bodies in the third direction, extending in a second plane formed by the first direction and the second direction, and at least partially covering the sidewalls of the first end of the semiconductor body extending in the first direction, wherein the third direction intersects with the second direction and a plane formed by the second direction and the third direction intersects with the first direction.

9. The memory device of claim 8, wherein the bit line is located at an end of the third portion of the first dielectric layer in the first direction and the third portion is spaced apart from the bit line in the first direction.

10. The memory device of claim 9, wherein the first dielectric layer further comprises:
a fourth portion located between at least two adjacent semiconductor bodies in the second direction, wherein an end of the third portion of the first dielectric layer proximate to the bit line in the first direction has a first distance from the bit line, an end of the fourth portion proximate to the bit line in the first direction has a second distance from the bit line, and the first distance is smaller than or equal to the second distance.

11. The memory device of claim 1, further comprising:
an isolation structure located between the at least two adjacent ones of the semiconductor bodies, wherein the isolation structure comprises the first dielectric layer, the second dielectric layer and an air gap enclosed by the second dielectric layer with the air gap proximate to the bit line in the first direction.

12. The memory device of claim 1, wherein a portion of the first dielectric layer covering the sidewalls of the first end of the semiconductor body extending in the first direction has a thickness in the second direction ranging from 0.1 nm to 2 nm.

13. The memory device of claim 1, wherein the first dielectric layer comprises a negative charge.

14. The memory device of claim 13, wherein the first dielectric layer has a dielectric constant larger than that of the second dielectric layer and is made of a material comprising at least one of aluminum oxide and hafnium oxide, and wherein the dielectric constant of the first dielectric layer ranges from 5 to 40.

15. A fabrication method of a memory device, comprising:
providing semiconductor bodies extending in a first direction, a semiconductor body comprising a first end and a second end disposed opposite to each other in the first direction, wherein a first dielectric material is filled between at least two adjacent ones of the semiconductor bodies comprising the semiconductor body, a second direction intersects with the first direction, a third direction intersects with the second direction, and a plane formed by the second direction and the third direction intersects with the first direction;
etching the first dielectric material between first ends of the semiconductor bodies adjacent in the third direction to form a first trench extending in the second direction, wherein sidewalls of the first trench expose a cavity between the first ends adjacent in the second direction;
forming a first dielectric layer on the sidewalls of the first trench and inner walls of the cavity, wherein the first dielectric layer at least partially covers sidewalls of the first end of the semiconductor body extending in the first direction; and
filling the first trench with a second dielectric material to form a second dielectric layer in both the trench and the cavity.

16. The fabrication method of claim 15, further comprising:
penetrating through the first dielectric layer on a bottom of the first trench in the first direction.

17. The fabrication method of claim 15, comprising:
forming a first dielectric material layer on the sidewalls of the first trench and the inner walls of the cavity;
filling the first trench and the cavity to form a sacrificial structure;
etching the first dielectric material layer in the first trench to lower a height of a top surface of the first dielectric material layer in the first trench in the first direction to form the first dielectric layer;
removing the sacrificial structure and forming the second dielectric layer;
filling a portion of the space within the first trench with the second dielectric material and filling a portion of the space within the cavity with the second dielectric material, wherein the second dielectric layer encloses an air gap; and
etching the first dielectric material layer to form a second trench extending in the second direction, wherein a bottom of the second trench is above or flush with the top inner wall of the cavity.

18. The fabrication method of claim 15, wherein the cavity exposes a conductive material layer between adjacent semiconductor bodies, the conductive material layer at least partially covering the sidewalls of the semiconductor body extending in the first direction, and
wherein the fabrication method further comprises:
etching a portion of the conductive material layer exposed from the cavity through the first trench to penetrate through, in the first direction, the portion of the conductive material layer extending in the second direction to form a gate layer;
forming the first dielectric layer on the gate layer, wherein a portion of the first dielectric layer extending in the second direction at least partially covers the gate layer; and
etching the gate layer along the first direction to reduce a dimension of the gate layer in the first direction, to form, on the gate layer, a third trench extending in the third direction and communicating with the cavity; and
forming the first dielectric layer on the inner walls of the cavity and inner walls of the third trench.

19. The fabrication method of claim 15, further comprising:
forming a bit line extending in the second direction on a side of the semiconductor body proximate to the first end, the bit line being coupled to the first end of the semiconductor body, wherein the first ends of the semiconductor bodies are connected by semiconductor strips and the first trench is located between adjacent semiconductor strips,
wherein forming the bit line comprises:
forming the bit line based on the semiconductor strips, wherein at least a portion of the bit line is located in the semiconductor strips and the bit line is located over the first dielectric layer.

20. A memory system, comprising:
a memory device, comprising:
semiconductor bodies extending in a first direction, a semiconductor body comprising a first end and a second end disposed opposite to each other in the first direction;
a bit line extending in a second direction intersecting the first direction, the bit line being located on a side of the semiconductor body proximate to the first end in the first direction and coupled to the first end of the semiconductor body;
a first dielectric layer located between at least two adjacent ones of the semiconductor bodies comprising the semiconductor body, the first dielectric layer at least partially covering sidewalls of the first end of the semiconductor body extending in the first direction; and
a second dielectric layer located between the at least two adjacent ones of the semiconductor bodies, wherein the first dielectric layer is located between the second dielectric layer and the semiconductor body; and
a memory controller coupled to and controlling the memory device.
